(19) United States
(12) Patent Application Publication
(10) Pub. No.: US 2025/0338481 A1
(43) Pub. Date: Oct. 30, 2025

(54) MEMORY DEVICE, AND SEMICONDUCTOR STRUCTURE AND METHOD FOR MANUFACTURING SAME

(71) Applicant: CXMT Corporation, Hefei City (CN)

(72) Inventors: Yexiao YU, Hefei City (CN); Yang ZHANG, Hefei City (CN); Zhongming LIU, Hefei City (CN); Wenshuai TANG, Hefei City (CN); Feng WANG, Hefei City (CN)

(73) Assignee: CXMT Corporation, Hefei City (CN)

(21) Appl. No.: 19/264,796

(22) Filed: Jul. 9, 2025

Related U.S. Application Data
(63) Continuation of application No. PCT/CN2025/078471, filed on Feb. 21, 2025.

(30) Foreign Application Priority Data
Apr. 3, 2024 (CN) 202410398933.4

(51) Int. Cl. H10B 12/00; H01L 23/00; H01L 25/065; H01L 25/18; H10B 80/00

(52) U.S. Cl. CPC H10B 12/315; H01L 24/08; H01L 25/0657; H01L 25/18; H10B 12/05; H10B 80/00; H01L 2224/08145; H01L 2924/1431; H01L 2924/1436

(57) ABSTRACT

Disclosed are a semiconductor structure and a method for manufacturing the same. The semiconductor structure includes: a substrate, where the substrate includes a plurality of active structures spaced apart along a first direction and a second direction, each of the plurality of active structures including a first active part and a second active part, and the substrate includes a first surface, each of the second active parts extending, along the corresponding first active part, towards the first surface and being provided with a first end surface in a direction facing the first surface; a plurality of contact structures, the plurality of contact structures being arranged on the first end surfaces of the second active parts; and a plurality of barrier layers arranged on the first surface and covering side walls of part of the second active parts and side walls of part of the plurality of contact structures.

### CROSS-REFERENCE TO RELATED APPLICATIONS

This application is a continuation of International Patent Application No. PCT/CN2025/078471 filed on Feb. 21, 2025, which claims priority to Chinese Patent Application No. 202410398933.4 filed on Apr. 3, 2024. The disclosures of the above-referenced applications are hereby incorporated by reference in their entirety.

### BACKGROUND

A memory is a memory component configured to store programs and various types of data information. A random access memory (RAM) used for a computer system may be classified into a dynamic random access memory (DRAM) and a static random-access memory (SRAM), and the DRAM is a semiconductor memory device commonly used in a computer and is composed of a plurality of repetitive memory cells.

The memory cell generally includes a capacitor and a transistor, where a drain of the transistor is connected to a bit line structure, a source of the transistor is connected to the capacitor, and the capacitor includes a capacitor contact structure and a capacitor. A word line structure of the memory cell can control a channel region of the transistor to be turned on or off, such that data information stored in the capacitor can be read through the bit line structure or the data information can be written into the capacitor through the bit line structure for storage.

With the rapid development of a semiconductor manufacturing technology, the semiconductor device is evolving towards higher element density and higher integration level. As semiconductor process nodes continue to become increasingly smaller following Moore's Law, there is a need to provide a new memory device, and a semiconductor structure and a method for manufacturing the same.

### SUMMARY

Embodiments of the present disclosure relate to the field of semiconductors, and in particular to a memory device, and a semiconductor structure and a method for manufacturing the same.

According to some embodiments of the present disclosure, one aspect of the embodiments of the present disclosure provides a semiconductor structure. The semiconductor structure includes:
a substrate, the substrate including a plurality of active structures spaced apart along a first direction and a second direction, where each of the plurality of active structures includes a first active part and a second active part,
the substrate includes a first surface, and each of the second active parts extends, along the corresponding first active part, towards the first surface and is provided with a first end surface in a direction facing the first surface;
a plurality of contact structures, the plurality of contact structures being arranged on the first end surfaces of the second active parts; and
a plurality of barrier layers arranged on the first surface and covering side walls of part of the second active parts and side walls of part of the plurality of contact structures.

According to some embodiments of the present disclosure, another aspect of the embodiments of the present disclosure further provides a method for manufacturing a semiconductor structure, which includes: providing a substrate; forming, in the substrate, a plurality of active structures spaced apart along a first direction and a second direction, each of the plurality of active structures including a first active part and a second active part, where the substrate includes a first surface, and each of the second active parts extends, along the corresponding first active part, towards the first surface and is exposed to the first surface; forming a plurality of barrier layers circumferentially around the second active parts, the plurality of barrier layers being arranged on the first surface and exposing first end surfaces of the second active parts; and forming a plurality of contact structures, the plurality of contact structures being arranged on the first end surfaces of the second active parts, and the plurality of barrier layers covering side walls of part of the second active parts and side walls of part of the plurality of contact structures.

### BRIEF DESCRIPTION OF DRAWINGS

One or more embodiments are exemplarily illustrated with reference to figures in the corresponding drawings, and these exemplary illustrations are not to be construed as limiting the embodiments. Unless expressly stated otherwise, the figures in the drawings do not constitute a limitation of scale. To more clearly illustrate the technical solutions in the embodiments of the present disclosure or conventional technology, a brief introduction to the drawings required to be used in the embodiments is given hereinafter. It is evident that the drawings described hereinafter are merely some embodiments of the present disclosure. For those of ordinary skill in the art, other drawings may be further obtained based on these drawings without creative effort.

FIG. 1 is a schematic diagram of a semiconductor structure according to an embodiment of the present disclosure.

FIG. 2 is a top view of the semiconductor structure shown in FIG. 1.

FIG. 3 is a flowchart of steps in a method for manufacturing a semiconductor structure according to an embodiment of the present disclosure.

FIGS. 4 to 14 are schematic structural diagrams, along a direction AA′ of a semiconductor structure, corresponding to steps in a method for manufacturing a semiconductor structure according to an embodiment of the present disclosure.

FIG. 15 is a schematic diagram of a semiconductor structure, in a direction AA′, including a plurality of capacitor structures according to an embodiment of the present disclosure.

FIGS. 16-17 are schematic structural diagrams, along a direction AA′, corresponding to a step of forming a plurality of bit lines in a method for manufacturing a semiconductor structure according to an embodiment of the present disclosure.

FIG. 18 is a top view of the corresponding schematic structural diagram after formation of the plurality of bit lines in FIG. 17.

FIG. 19 is a schematic diagram of a semiconductor structure, along a direction AA′, including a bonding layer according to an embodiment of the present disclosure.

FIG. 20 is a schematic diagram of a process step for forming a memory device by bonding.

### DETAILED DESCRIPTION

The embodiments of the present disclosure will be described in detail below with reference to the drawings. However, those of ordinary skill in the art can understand that, in the embodiments of the present disclosure, numerous technical details are set forth to enable readers to better understand the present disclosure. However, the technical solutions claimed by the present disclosure can also be implemented even without these technical details and the various changes and modifications based on the following embodiments.

The present disclosure does not limit the type of a transistor, and is introduced below with a vertical gate-all-around (VGAA) transistor as an example, the VGAA transistor may be applied to a drive transistor of a logic device, and drive transistors of a dynamic random access memory (DRAM), a magnetic random access memory (MRAM), and other memory devices, and the present disclosure is not limited thereto. The memory includes a plurality of memory cells arranged in an array, where each of the plurality of memory cells includes a VGAA transistor, a capacitor contact structure connected to a source of the VGAA transistor, a word line connected to a gate, and a bit line connected to a drain, and the plurality of capacitor contact structures and the plurality of capacitor structures are sequentially formed on the substrate. In the VGAA transistors, the plurality of capacitor structures with a certain height are formed along a direction perpendicular to the substrate, and a process difficulty in electrically connecting the plurality of capacitor structures to the transistors through the plurality of capacitor contact structures is large. In particular, since each of the plurality of capacitor contact structures has a small dimension, short-circuiting between the transistors and the plurality of capacitor structures is easily generated when the plurality of capacitor structures are formed.

To solve the above problems, an embodiment of the present disclosure provides a semiconductor structure. The semiconductor structure according to this embodiment of the present disclosure is described below with reference to the drawings.

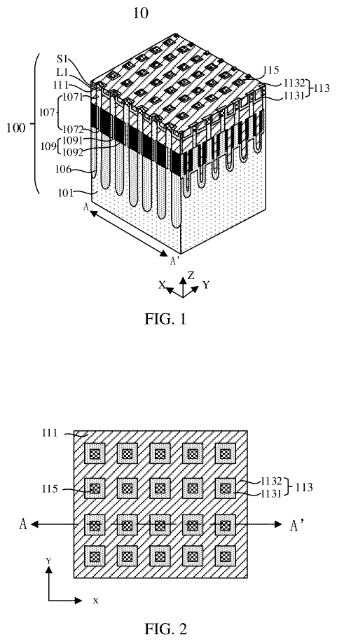

FIG. 1 is a schematic diagram of a semiconductor structure according to an embodiment of the present disclosure; and FIG. 2 is a top view of the semiconductor structure shown in FIG. 1. Referring to FIGS. 1 and 2, the semiconductor structure 10 according to the embodiment of the present disclosure includes: a substrate 100 including a plurality of active structures 107 spaced apart along a first direction X and a second direction Y, each of the plurality of active structures 107 including a first active part 1072 and a second active part 1071, where the substrate 100 includes a first surface S1, and each of the second active parts 1071 extends, along the corresponding first active part 1072, towards the first surface S1 and is provided with a first end surface L1 in a direction facing the first surface S1; a plurality of contact structures 115 arranged on the first end surfaces L1 of the second active parts 1071; and a plurality of barrier layers 113 arranged on the first surface S1 and covering side walls of part of the second active parts 1071 and side walls of part of the plurality of contact structures 115, which are described in detail below with reference to the drawings.

With continued reference to FIGS. 1 and 2, the substrate 100 includes the plurality of active structures 107 spaced apart along the first direction X and the second direction Y, where the first direction X and the second direction Y may be a row direction and a column direction within a plane parallel to the substrate 100 shown in FIG. 1, respectively, and a third direction Z may be a direction from a top surface of the substrate 100 to a bottom surface of the substrate 100 in FIG. 1, the X direction, the Y direction, and the Z direction being perpendicular to each other. The substrate 100 may further include a base substrate 101, illustratively, the first surface S1 is a plane of the substrate 100 extending along the first direction X and the second direction Y and facing away from the base substrate 101, each of the second active parts 1071 extends, along the corresponding first active part 1072, towards the first surface S1, and is provided with a first end surface L1 in a direction facing the first surface S1, i.e., the first surface S1 exposes the first end surfaces L1 of the second active parts 1071. The first end surfaces L1 of the second active parts 1071 may be sources or drains.

The plurality of contact structures 115 are arranged on the first end surfaces L1 of the second active parts 1071, the plurality of contact structures 115 respectively correspond to the plurality of active structures 107 spaced apart along the first direction X and the second direction Y, and each of the plurality of contact structures 115 is electrically connected to the corresponding active structure 107 through the first end surface L1, i.e., the source or the drain, of the corresponding second active part 1071.

Referring to FIG. 1, the barrier layers 113 are arranged on the first surface S1 and cover the side walls of part of the second active parts 1071 and the side walls of part of the plurality of contact structures 115. The barrier layers 113 are disposed on the side walls of part of the second active parts 1071 and the side walls of part of the plurality of contact structures 115, such that the influence, on the plurality of active structures 107, of a subsequent process for forming the plurality of capacitor structures can be avoided, and short-circuiting between the plurality of capacitor structures and the plurality of active structures 107 is avoided.

In some embodiments, each of the plurality of barrier layers 113 may include a first barrier layer 1131 and a second barrier layer 1132, the first barrier layers 1131 covering the side walls of part of the second active parts 1071 and the side walls of part of the plurality of contact structures 115, and the second barrier layers 1132 covering part of the first barrier layers 1131. Illustratively, the top surfaces of the first barrier layer 1131 and the second barrier layer 1132 may be flush, which is beneficial to ensuring that the plurality of contact structures 115 are accurately formed on the first end surfaces L1 of the second active parts 1071.

In some embodiments, as shown in FIG. 11, the plurality of contact structures 115 further cover the top surfaces of part of the first barrier layers 1131, and the plurality of contact structures 115 extend in a direction parallel to the second barrier layers 1132 and cover part of the top surfaces of the first barrier layers 1131, such that surface areas of the plurality of contact structures 115 are effectively increased, and after the plurality of capacitor structures are formed subsequently, the contact areas between the plurality of capacitor structures and the plurality of contact structures 115 can be effectively increased, thereby facilitating reduction of a contact resistance.

In some embodiments, the first barrier layer 1131 has a different etching selectivity from the second barrier layer 1132. Illustratively, the first barrier layer 1131 may be made of silicon oxide, the second barrier layer 1132 may be made of silicon nitride, and the first barrier layer and the second barrier layer are made of different materials. When an etching process is performed, the first barrier layer has a different selectivity from the second barrier layer, and when a subsequent capacitor process is performed, the first barrier layers 1131 can be retained intact, thereby effectively avoiding the substrate 100 from being over-etched, which can lead to short-circuiting between the plurality of capacitor structures and the plurality of active structures 107.

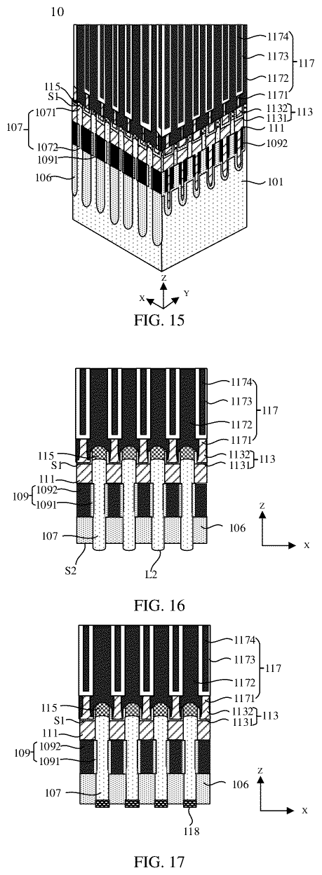

In some embodiments, referring to FIGS. 14 and 15, the semiconductor structure 10 further includes the plurality of capacitor structures 117 disposed on the substrate 100 and electrically connected to the plurality of active structures 107 through the plurality of contact structures 115, where each of the plurality of capacitor structures 117 includes a lower electrode 1172 and an upper electrode 1174, each of the plurality of capacitor structures 117 is electrically connected to the corresponding active structure 107 through the corresponding lower electrode 1172, the lower electrodes 1172 and the upper electrodes 1174 may be made of the same material, the lower electrodes 1172 and the upper electrodes 1174 may be made of at least one of platinum nickel, titanium, tantalum, cobalt, polycrystalline silicon, copper, tungsten, tantalum nitride, titanium nitride, or ruthenium, and in other embodiments, a lower electrode layer and an upper electrode layer may also be made of different materials.

Each of the plurality of capacitor structures 117 further includes a support layer 1171 and a dielectric layer 1173 arranged on the support layer 1171. In some embodiments, the dielectric layers 1173 may be made of silicon oxide, tantalum oxide, hafnium oxide, zirconium oxide, niobium oxide, titanium oxide, barium oxide, strontium oxide, yttrium oxide, lanthanum oxide, praseodymium oxide, or barium strontium titanate, or other high-k materials. The support layers 1171 are disposed on the corresponding second barrier layers 1132. The support layers 1171 may be made of at least one of silicon nitride or silicon carbonitride, and the support layers 1171 have a greater hardness, which is beneficial to supporting the plurality of capacitor structures 117 and preventing the plurality of capacitor structures 117 from collapsing. In some embodiments, the support layers 1171 have a different etching selectivity from the first barrier layers 1131, or the support layers 1171 and the second barrier layers 1132 are made of the same material, when the support layers are etched to form the plurality of capacitor structures 117, it can be ensured that the first barrier layers 1131 are not etched, such that the substrate 100 can be ensured not to be over-etched, thereby avoiding short-circuiting between the plurality of capacitor structures 117 and the plurality of active structures 107.

In some embodiments, referring to FIGS. 11 and 13, a spacing d2 between the top surfaces of the support layers 1171 of adjacent capacitor structures 117 may be greater than a width d1 of each of the plurality of contact structures 115 along the first direction, so as to ensure that the plurality of contact structures 115 can be completely exposed to the support layers, and to ensure the contact areas between the lower electrodes 1172 and the plurality of contact structures 115.

In some embodiments, referring to FIG. 16, the substrate 100 may further include: a second surface S2, the second end surfaces L2 of the first active parts 1072 being exposed to the second surface S2; a plurality of word lines 109, the plurality of word lines 109 being disposed around the plurality of active structures 107 and partially coinciding with the first active parts 1072; a plurality of bit lines 118, the plurality of bit lines 118 being arranged on the second surface S2 of the substrate 100, and the plurality of bit lines 118 being electrically connected to the plurality of active structures 107 through the second end surfaces L2 of the first active parts 1072; and a bonding layer L3, the bonding layer L3 being arranged on the second surface S2, and being connected to the plurality of word lines 109, the plurality of bit lines 118 and the plurality of capacitor structures 117 through bonding structures 120, which will be described in detail with reference to the drawings.

As shown in FIG. 16, the substrate 100 further includes a second surface S2, the second end surfaces L2 of the first active parts 1072 being exposed to the second surface S2. Illustratively, each of the plurality of active structures 107 includes a source, a drain and a channel region, where the source or the drain may be arranged on the second end surface L2 of the corresponding first active part 1072 facing the second surface S2 and the first end surface L1 of the corresponding second active part 1071 facing the first surface S1, respectively, and each of the channel regions is arranged between the corresponding source and the corresponding drain.

With continued reference to FIGS. 15 and 16, the substrate 100 may further include a plurality of mutually separated word lines 109, where each of the plurality of word lines 109 extends along the second direction Y, and includes: a gate oxide layer 1091, where each of the gate oxide layers 1091 is circumferentially disposed in the corresponding channel region of the corresponding active structure 107 and covers a surface of a side wall of the channel region of the active structure 107; and a gate conductive layer 1092, where each of the gate conductive layers 1092 surrounds the corresponding channel region and is arranged on a surface of a side wall of the gate oxide layer 1091 corresponding to the channel region. Each of the channel regions is disposed between the corresponding source and the corresponding drain of each of the plurality of active structures 107, and for each of the plurality of word lines 109, the plurality of word lines 109 are disposed around the channel regions of at least one active structure 107 and partially coincide with the first active parts 1072. Illustratively, the gate conductive layers 1092 may be made of at least one of tungsten, titanium nitride, and other metals or metal compounds, and the gate oxide layers 1091 may be made of silicon oxide.

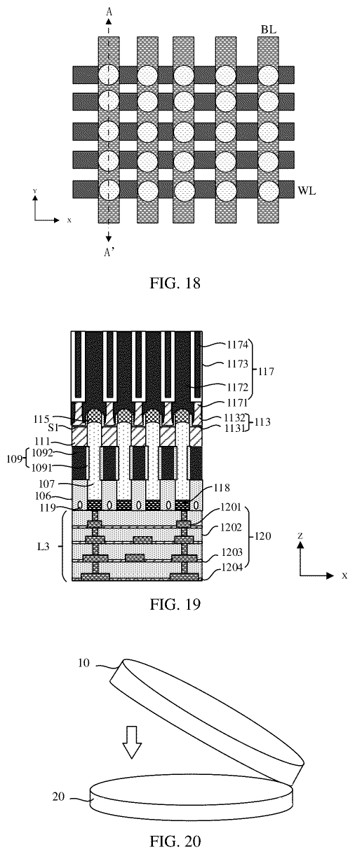

In some embodiments, as shown in FIGS. 16 and 17, the second surface S2 of the substrate 100 is further provided with a plurality of mutually separated bit lines 118, each of the plurality of bit lines 118 extending along the first direction X, and each of the plurality of bit lines 118 being formed by a conductive layer; illustratively, the conductive layers may be made of a metal or a metal compound, such as, at least one of cobalt, nickel, molybdenum, titanium, tungsten, tantalum, or platinum, or at least one of cobalt silicide, nickel silicide, molybdenum silicide, titanium silicide, tungsten silicide, tantalum silicide, or platinum silicide. The second end surfaces L2 of the first active parts 1072 may be the sources or the drains, and each of the plurality of bit lines 118 is electrically connected to the corresponding active structure 107 through the first end surface L2, i.e., the source or the drain, of the corresponding first active part 1072, respectively. FIG. 18 is a top view of the semiconductor structure after formation of the plurality of bit lines 118, a plurality of bit lines (BLs), i.e., the plurality of bit lines 118, being spaced apart along the first direction X, and a plurality of word lines (WL), i.e., the plurality of word lines 109, being spaced apart along the second direction Y, as shown in FIG. 18.

In some embodiments, as shown in FIG. 16, the bonding layer L3 is arranged on the second surface S2 of the substrate 100 and is connected to the plurality of word lines 109, the plurality of bit lines 118 and the plurality of capacitor structures 117 through the bonding structures 120; referring to FIG. 19, each of the bonding structures 120 consists of a metal wiring layer 1201, a block layer 1202, an insulating layer 1203, and a passivation layer 1204. The metal wiring layer 1201 on the surface of the bonding layer L3 serves as a bonding pad through which the semiconductor structure can be bonded to a bonded wafer during subsequent forming of a memory device.

In summary, the barrier layers 113 are disposed on the side walls of part of the second active parts 1071 and the side walls of part of the plurality of contact structures 115, such that the influence, on the plurality of active structures 107, of a subsequent process for forming the plurality of capacitor structures can be avoided, and short-circuiting between the plurality of capacitor structures and the plurality of active structures 107 is avoided. Furthermore, each of the disposed barrier layers 113 includes the first barrier layer 1131 and the second barrier layer 1132, where the first barrier layers 1131 cover the side walls of part of the second active parts 1071 and the side walls of part of the plurality of contact structures 115, the second barrier layers 1132 cover part of the first barrier layers 1131, and the top surface of the first barrier layer 1131 and the top surface of the second barrier layer 1132 are flush, which is beneficial to ensuring that the plurality of contact structures 115 are accurately formed on the first end surfaces L1 of the second active parts 1071; and in addition, the first barrier layer 1131 has a different etching selectivity from the second barrier layer 1132, therefore, when the subsequent capacitor process is performed, the first barrier layers 1131 can be retained intact, thereby ensuring that the substrate 100 is not over-etched, and the short-circuiting between the plurality of capacitor structures 117 and the plurality of active structures 107 is avoided.

Accordingly, yet another embodiment of the present disclosure provides a method for manufacturing a semiconductor structure, which can be used for forming the semiconductor structure described above.

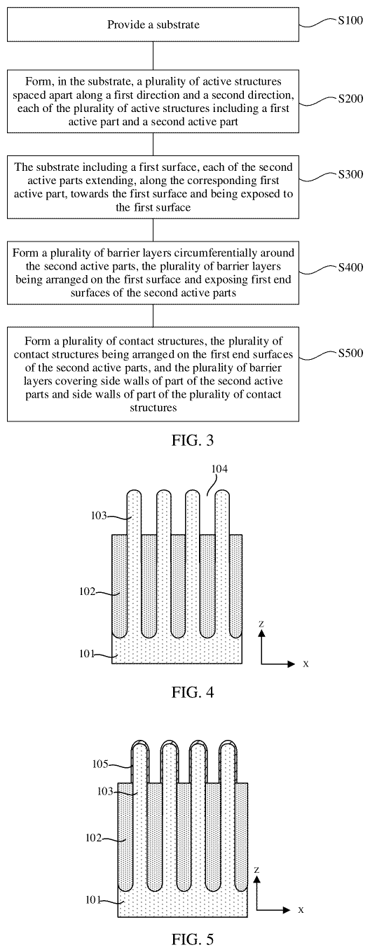

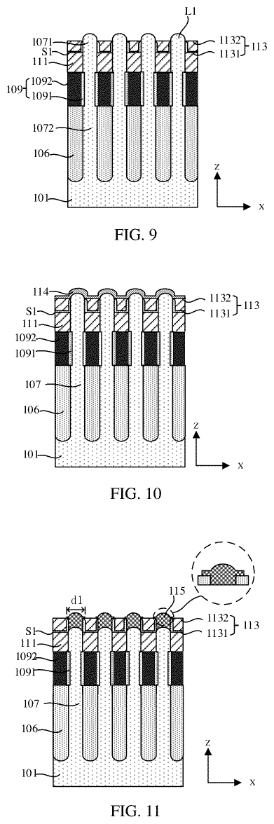

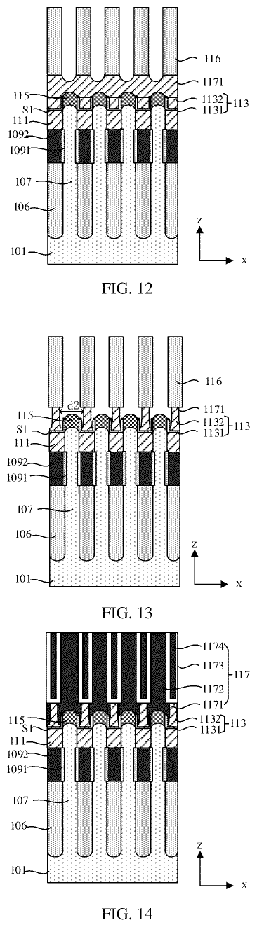

FIG. 3 is a flowchart of steps in the method for manufacturing a semiconductor structure according to an embodiment of the present disclosure. FIGS. 4-14 and FIGS. 16-19 are schematic diagrams showing cross-sectional structures, along a direction AA′, corresponding to steps in a method for manufacturing a semiconductor structure according to yet another embodiment of the present disclosure. The method for manufacturing a semiconductor structure according to the embodiment of the present disclosure is described in detail below with reference to the drawings, and content that is the same as or that corresponds to the content of the above embodiments is not described in detail below again.

In step S100, the substrate 100 is provided.

In step S200, a plurality of active structures 107 spaced apart along a first direction X and a second direction Y are formed in the substrate 100, each of the plurality of active structures 107 including a first active part 1072 and a second active part 1071, where the substrate 100 includes a first surface S1, and each of the second active parts 1071 extends, along the corresponding first active part 1072, towards the first surface S1 and is exposed to the first surface S1.

In some embodiments, referring to FIGS. 4-6, a base substrate 101 is provided, where the base substrate 101 may be made of monocrystalline silicon (Si), monocrystalline germanium (Ge), silicon germanium (GeSi), or silicon carbide (SiC), or may be made of silicon-on-insulator (SOI), germanium-on-insulator (GOI), or may also be made of another material, for example, a group III-V compound, e.g., gallium arsenide.

The base substrate 101 is etched to form a plurality of through holes 104 spaced apart along the first direction X and the second direction Y and a plurality of initial active structures 103 adjacent to the plurality of through holes 104. Each of the plurality of initial active structures 103 includes a source/drain region, a channel region and a source/drain region sequentially disposed along a third direction Z, where the source regions, the channel regions and the drain regions have the same type of doping ions, and for example, all of the doping ions may be N-type doping ions or P-type doping ions. Part of the plurality of through holes 104 are filled to form a plurality of isolation layers 102, the plurality of isolation layers 102 exposing part of the plurality of initial active structures 103, where the plurality of isolation layers 102 may be made of an insulating material, for example, may be made of silicon oxide.

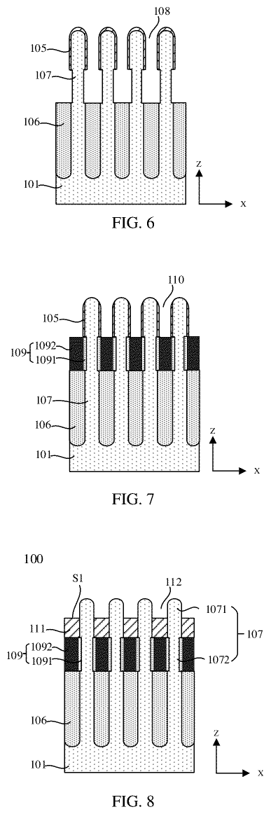

A plurality of protective layers 105 are formed, the plurality of protective layers 105 covering the plurality of initial active structures 103 exposed by the plurality of isolation layers 102; etching is performed by using the plurality of protective layers 105 as masks to remove part of the plurality of isolation layers 102 and part of the plurality of initial active structures 103 to form a plurality of first trenches 108, the rest part of the plurality of initial active structures 103 forming the plurality of active structures 107, and the rest part of the plurality of isolation layers 102 forming a plurality of isolation structures 106. As shown in FIG. 6, in an etching process, formation of the protective layers 105 ensures that the end surfaces and part of side walls of the initial active structures 103 are not etched, thereby ensuring the integrity of the plurality of active structures 107.

In step S300, a plurality of barrier layers 113 are circumferentially formed around the second active parts 1071, the plurality of barrier layers 113 being arranged on the first surface S1 and exposing the first end surfaces L1 of the second active parts 1071.

In some embodiments, referring to FIGS. 6-9, after formation of the plurality of active structures 107, a plurality of gate oxide layers 1091 may be deposited firstly in the plurality of first trenches 108, and then the plurality of gate oxide layers 1091 may be patterned to form a plurality of gate oxide layers 1091 covering the side walls of part of the plurality of active structures 107. The plurality of gate oxide layers 1091 may be high-K dielectric layers, for example, may be silicon oxide, to improve the performance of the semiconductor structure. In other embodiments of the present disclosure, the plurality of gate oxide layers 1091 may also be formed directly on the side surfaces of the plurality of active structures 107.

The gate conductive layers 1092 are formed on the surfaces of the plurality of isolation structures 106 away from the base substrate 101 and side surfaces of the gate oxide layers 1091, the gate oxide layers 1091 and the gate conductive layers 1092 jointly form the plurality of word lines 109, the surfaces of the plurality of word lines 109 are flush with the bottom surfaces of the protective layers 105, and the side walls of the protective layers 105 and the surfaces of the plurality of word lines 109 jointly form a plurality of second trenches 110, where the surfaces of the plurality of word lines 109 face away from the base substrate 101, and the bottom surfaces of the protective layers 105 face the base substrate 101.

Specifically, the gate conductive layers 1092 are formed by a chemical vapor deposition (CVD) process, a physical vapor deposition (PVD) process, an atomic layer deposition (ALD) process, or a metal organic chemical vapor deposition (MOCVD) process, etc. on the surfaces of the plurality of isolation structures 106 facing away from the base substrate 101 and on the side surfaces of the gate oxide layers 1091. The plurality of gate conductive layers 1092 may be made of polycrystalline silicon, TiN, TaN, Al, W, Cu, etc., and the gate conductive layers 1092 may be flush with the channel regions of the plurality of active structures 107 and extend along the second direction Y.

The plurality of second trenches 110 are filled to form a plurality of insulating layers 111, the plurality of insulating layers 111 cover the plurality of word lines 109, the plurality of insulating layers 111 are etched back until the second active parts 1071 are exposed, and the second active parts 1071 and the plurality of insulating layers 111 jointly form a plurality of third trenches 112, where the plurality of insulating layers may be made of silicon nitride. Referring to FIG. 8, the base substrate 101, the plurality of isolation structures 106, the plurality of word lines 109, the plurality of active structures 107, and the plurality of insulating layers 111 jointly form the substrate 100.

A plurality of barrier layers 113 are formed in the plurality of third trenches 112, where each of the plurality of barrier layers 113 may include a first barrier layer 1131 and a second barrier layer 1132, the plurality of barrier layers 113 are etched to expose the first end surfaces L1 of the second active parts 1071, and the first end surfaces L1 may be the sources or drains of the plurality of active structures 107; and the rest of the plurality of barrier layers 113 cover the side walls of part of the plurality of active structures 107, i.e., the first barrier layers 1131 cover part of the side walls of part of the second active parts 1071, and the second barrier layers 1132 cover part of the first barrier layers 1131. The first barrier layer 1131 has a different etching selectivity from the second barrier layer 1132, illustratively, the first barrier layer 1131 may be made of silicon oxide, the second barrier layer 1132 may be made of silicon nitride, and a selectivity of the silicon oxide to the silicon nitride is 1:20.

In step S400, a plurality of contact structures 115 are formed, the plurality of contact structures 115 being arranged on the first end surfaces L1 of the second active parts 1071, and the barrier layers 113 covering the side walls of part of the second active parts 1071 and the side walls of part of the plurality of contact structures 115.

Specifically, in some embodiments, referring to FIGS. 10 and 11, a plurality of metal layers 114 are firstly deposited, the plurality of metal layers 114 covering the plurality of barrier layers 113 and the first end surfaces L1 of the second active parts 1071, and illustratively, a sputtering process may be used to form a metal on the first end surfaces L1 of the second active parts 1071. The plurality of metal layers 114 are subjected to a high-temperature treatment, in a high-temperature annealing process, a metal silicide may be formed on the first end surfaces L1 of the second active parts 1071 due to a diffusion effect, the plurality of metal layers 114 covering the plurality of barrier layers 113 are removed, and the metal layers 114 on the first end surfaces L1 are retained to form the plurality of contact structures 115. After formation of the plurality of contact structures 115, removing the plurality of metal layers 114 on the plurality of barrier layers 113 is further included. The metal silicide may be at least one of cobalt silicide, nickel silicide, platinum silicide or nickel platinum silicide.

As shown by portions outlined by dotted lines in FIG. 11, when the plurality of metal layers 114 covering the plurality of barrier layers 113 are removed, only the plurality of metal layers 114 on the plurality of second barrier layers 1132 may be removed, the plurality of contact structures 115 formed finally may cover the top surfaces of part of the plurality of first barrier layers 1131, and the plurality of contact structures 115 extend in a direction parallel to the plurality of second barrier layers 1132 and cover part of the top surfaces of the plurality of first barrier layers 1131, so as to effectively increase a surface area of the plurality of contact structures 115, and further, after a plurality of capacitor structures 117 are formed subsequently, the contact area between the plurality of capacitor structures 117 and the plurality of contact structures 115 can be effectively increased, which is beneficial to reducing the contact resistance.

In some embodiments, the method for manufacturing a semiconductor structure 10 further includes forming the plurality of capacitor structures 117, as shown in FIGS. 11-15. Each of the plurality of capacitor structures 117 includes a support layer 1171 and a dielectric layer 1173 formed on the support layer 1171, each of the support layers 1171 being formed on the corresponding second barrier layer 1132. Illustratively, the support layers 1171 and a plurality of sacrificial layers 116 are sequentially deposited on the plurality of contact structures 115 and the plurality of barrier layers 113, the plurality of sacrificial layers 116 are formed on the corresponding support layers 1171, and a deposition process includes, but is not limited to, a CVD process, a PVD process, an ALD process, or an MOCVD process; and part of the plurality of sacrificial layers 116 and part of the support layers 1171 are etched in different steps to expose the plurality of contact structures 115, where the plurality of etched sacrificial layers 116 and the etched support layers 1171 are spaced apart along the first direction X and the second direction Y, and the etching process may include at least one of photolithography, wet etching, or dry etching. The plurality of sacrificial layers 116 may be made of a low-k dielectric material, borosilicate, borophosphosilicate glass, tetraethyl silicate, silicon oxide, etc., and the support layers 1171 may be made of silicon nitride.

During the course of forming the plurality of capacitor structures 117, when the support layers 1171 are etched downwards along the third direction Z to expose the plurality of contact structures 115, since the plurality of barrier layers 113 cover the substrate 100, an etchant can be effectively blocked from further etching the substrate 100 during an etching process, thereby preventing the plurality of active structures 107 from being exposed to the substrate 100. In some embodiments, the support layers 1171 have a different etching selectivity from the first barrier layers 1131, or the support layers and the second barrier layers 1132 are made of the same material, such as silicon nitride. The etched support layers 1171 are arranged on the corresponding second barrier layers 1132, since the first barrier layers 1131 have a different etching selectivity from the second barrier layers 1132, the support layers 1171 have a different etching selectivity from the first barrier layers 1131, or the support layers 1171 and the second barrier layers 1132 are made of the same material, therefore when the support layers 1171 are etched to expose the plurality of contact structures 115, the first barrier layers 1131 can be retained intact, and the substrate 100 is prevented from being over-etched, thus protecting the plurality of active structures 107 from being exposed to the substrate 100, and further avoiding the plurality of capacitor structures 117 from being in a short circuit with the plurality of active structures 107.

The lower electrodes 1172 are deposited in the trenches formed by the etched support layers 1171, the plurality of etched sacrificial layers 116 and the plurality of contact structures 115, and bottoms of the lower electrodes 1172 are electrically connected to the plurality of active structures 107 through the plurality of contact structures 115. NiPt, Ti, Ta, W, Co, Ru, Cu, TaN, TiN, or polycrystalline silicon and other metals are formed as the lower electrodes 1172 by the CVD process, the PVD process, the ALD process, the MOCVD process, or other processes; and the plurality of sacrificial layers 116 are removed to expose at least the upper surfaces of the sides of the lower electrodes 1172 facing away from the base substrate 101, and in this step, the surfaces of the sides of the support layers 1171 facing away from the base substrate 101 are also exposed.

The dielectric layers 1173 are formed on the surfaces of the lower electrodes 1172, and in this step, the dielectric layers 1173 may be formed by the CVD process, the PVD process, the ALD process, the MOCVD process, or other processes. The dielectric layers 1173 cover not only the upper surfaces of the lower electrodes 1172 but also the surfaces of the support layers 1171, where the dielectric layers 1173 may be made of a high-K dielectric material.

The upper electrodes 1174 are formed on the surfaces of the dielectric layers 1173, in this step, a metal of NiPt, Ti, Ta, W, Co, Ru, Cu, TaN, TiN, or polycrystalline silicon or other materials is deposited on the surfaces of the dielectric layers 1173 as the upper electrodes 1174, and the upper electrodes 1174 cover the dielectric layers 1173. The support layers 1171, the lower electrodes 1172, the dielectric layers 1173, and the upper electrodes 1174 jointly form the plurality of capacitor structures 117. The spacing d2 between the top surfaces of the support layers 1171 of adjacent capacitor structures 117 is greater than the width d1 of each of the plurality of contact structures 115 along the first direction, so as to ensure that the plurality of contact structures 115 can be completely exposed to the support layers 1171, and to ensure a contact area between each of the lower electrodes 1172 and the corresponding contact structure 115.

As shown in FIGS. 14-19, the method for manufacturing a semiconductor structure 10 further includes forming a plurality of bit lines 118, the substrate 100 may further include a second surface S2, the plurality of bit lines 118 are formed on the second surface S2 of the substrate 100 and extend along the first direction X, the plurality of bit lines 118 are spaced apart along the second direction Y, the second end surfaces L2 of the first active parts 1072 are exposed to the second surface S2, and the plurality of bit lines 118 are electrically connected to the plurality of active structures 107 through the second end surfaces L2 of the first active parts 1072. Illustratively, the plurality of isolation structures 106 of the substrate 100 are etched along the third direction Z to expose the second end surfaces L2 of the first active parts 1072, and the second end surfaces L2 of the first active parts are subjected to silicidation to form the plurality of bit lines 118, for example, metal ion deposition and high-temperature annealing are conducted to form a metal silicide as the conductive layer of each of the plurality of bit lines 118, where the metal silicide may be at least one of cobalt silicide, nickel silicide, platinum silicide, or nickel platinum silicide. As shown in FIG. 19, in some embodiments, air gaps 119 may also be formed in end parts, facing the second surface S2, of two adjacent isolation structures 106 between which each of the plurality of bit lines 118 is disposed, so as to reduce a coupling capacitance between the adjacent bit lines 118.

As shown in FIG. 19, the method for manufacturing a semiconductor structure 10 further includes forming a bonding layer L3, where the bonding layer L3 is arranged on the second surface S2 of the substrate 100 and is connected to the plurality of word lines 109, the plurality of bit lines 118 and the plurality of capacitor structures 117 through bonding structures 120. Illustratively, block layers 1202, metal wiring layers 1201, insulating layers 1203, and passivation layers 1204 are sequentially deposited and formed on the second surface S2 of the substrate 100. The block layer 1202, the metal wiring layer 1201, the insulating layer 1203 and the passivation layer 1204 jointly form the bonding structure 120, and the metal wiring layer 1201 on the surface of the bonding layer L3 is used as the bonding pad through which the semiconductor structure may be bonded to the bonded wafer during subsequent forming of the memory device.

The present embodiment further provides a memory device formed by bonding the semiconductor structure 10 to the bonded wafer 20, as shown in FIGS. 19 and 20, the bonded wafer 20 includes a control circuit and a bonding interface, and the memory device is formed by bonding the bonding layer L3 of the semiconductor structure 10 to the bonding interface of the bonded wafer 20.

Those of ordinary skill in the art can understand that the foregoing implementations are specific embodiments of the present disclosure, and in practical application, various changes may be made in form and detail without departing from the spirit and scope of the embodiments of the present disclosure. Any person skilled in the art can make various changes and modifications without departing from the spirit and scope of the embodiments of the present disclosure, and the protection scope of the embodiments of the present disclosure is defined by the appended claims.

What is claimed is:

1. A semiconductor structure, comprising:
a substrate, the substrate comprising a plurality of active structures spaced apart along a first direction and a second direction, wherein each of the plurality of active structures comprises a first active part and a second active part,
the substrate comprises a first surface, and each of the second active parts extends, along the corresponding first active part, towards the first surface and is provided with a first end surface in a direction facing the first surface;
a plurality of contact structures, the plurality of contact structures being arranged on the first end surfaces of the second active parts; and
a plurality of barrier layers, arranged on the first surface and covering side walls of part of the second active parts and side walls of part of the plurality of contact structures.

2. The semiconductor structure according to claim 1, wherein each of the plurality of barrier layers comprises a first barrier layer and a second barrier layer, the first barrier layers covering the side walls of part of the second active parts and the side walls of part of the plurality of contact structures, the second barrier layers covering part of the first barrier layers, and the first barrier layer having a different etching selectivity from the second barrier layer.

3. The semiconductor structure according to claim 2, further comprising a plurality of capacitor structures, the plurality of capacitor structures being disposed on the substrate and electrically connected to the plurality of active structures through the plurality of contact structures.

4. The semiconductor structure according to claim 3, wherein each of the plurality of capacitor structures comprises a support layer and a dielectric layer arranged on the support layer, the support layer being disposed on the corresponding second barrier layer.

5. The semiconductor structure according to claim 4, wherein a spacing between top surfaces of the support layers of adjacent capacitor structures is greater than a width of each of the plurality of contact structures along the first direction.

6. The semiconductor structure according to claim 4, wherein the support layers have a different etching selectivity from the first barrier layers.

7. The semiconductor structure according to claim 4, wherein the support layers are made of the same material as the second barrier layers.

8. The semiconductor structure according to claim 3, wherein the substrate further comprises:
a second surface, second end surfaces of the first active parts being exposed to the second surface of the substrate;
a plurality of word lines, the plurality of word lines being disposed around the plurality of active structures and partially coinciding with the first active parts;
a plurality of bit lines, the plurality of bit lines being arranged on the second surface of the substrate, and the plurality of bit lines being electrically connected to the plurality of active structures through the second end surface of the first active parts; and
a bonding layer, the bonding layer being arranged on the second surface and connected to the plurality of word lines, the plurality of bit lines, and the plurality of capacitor structures through bonding structures.

9. A method for manufacturing a semiconductor structure, comprising:
providing a substrate;
forming, in the substrate, a plurality of active structures spaced apart along a first direction and a second direction, each of the plurality of active structures comprising a first active part and a second active part, wherein
the substrate comprises a first surface, and each of the second active parts extends, along the corresponding first active part, towards the first surface and is exposed to the first surface;
forming a plurality of barrier layers circumferentially around the second active parts, the plurality of barrier layers being arranged on the first surface and exposing first end surfaces of the second active parts; and
forming a plurality of contact structures, the plurality of contact structures being arranged on the first end surfaces of the second active parts, and the plurality of barrier layers covering side walls of part of the second active parts and side walls of part of the plurality of contact structures.

10. The method for manufacturing a semiconductor structure according to claim 9,
wherein a process step of forming, in the substrate, the plurality of active structures spaced apart along the first direction and the second direction comprises:
providing a base substrate;
etching the base substrate to form a plurality of through holes spaced apart along the first direction and the second direction and a plurality of initial active structures adjacent to the plurality of through holes;
filling part of the plurality of through holes to form a plurality of isolation layers, the plurality of isolation layers exposing part of the plurality of initial active structures;
forming a plurality of protective layers, the plurality of protective layers covering the plurality of initial active structures exposed by the plurality of isolation layers; and
performing etching by using the plurality of protective layers as masks to remove part of the plurality of isolation layers and part of the plurality of initial active structures to form a plurality of first trenches, the rest part of the plurality of isolation layers forming isolation structures, and the rest part of the plurality of initial active structures forming the plurality of active structure.

11. The method for manufacturing a semiconductor structure according to claim 10, wherein a process step of forming the plurality of barrier layers circumferentially around the second active parts, the plurality of barrier layers being arranged on the first surface and exposing the first end surfaces of the second active parts comprises:
depositing a gate oxide layer in each of the plurality of first trenches, the gate oxide layers covering side walls of part of the plurality of active structures;
forming a gate conductive layer on a surface of each of the isolation structures and a side surface of each of the gate oxide layers, the gate oxide layers and the gate conductive layers jointly forming a plurality of word lines, a surface of each of the plurality of word lines being flush with a bottom surface of each of the protective layers, and side walls of each of the protective layers and the surface of each of the plurality of word lines jointly forming each of a plurality of second trenches;
filling the plurality of second trenches to form a plurality of insulating layers, the plurality of insulating layers covering the plurality of word lines, and etching back the plurality of insulating layers until the second active parts are exposed, the second active parts and the insulating layers jointly forming a plurality of third trenches;
forming the plurality of barrier layers in the plurality of third trenches, each of the plurality of barrier layers comprising a first barrier layer and a second barrier layer, the first barrier layers covering side walls of part of the second active parts and side walls of part of the plurality of contact structures, the second barrier layers covering part of the first barrier layers, and the first barrier layers having a different etching selectivity from the second barrier layers; and
etching the plurality of barrier layers to expose the first end surfaces of the second active parts.

12. The method for manufacturing a semiconductor structure according to claim 9, wherein a process step of forming the plurality of contact structures, the plurality of contact structures being arranged on the first end surfaces of the second active parts comprises:
depositing a plurality of metal layers, the plurality of metal layers covering the plurality of barrier layers and the first end surfaces of the second active parts; and
performing high-temperature treatment on the plurality of metal layers, removing the plurality of metal layers covering the plurality of barrier layers, and retaining the plurality of metal layers on the first end surfaces to form the plurality of contact structures.

13. The method for manufacturing a semiconductor structure according to claim 11, further comprising:
forming a plurality of capacitor structures, each of the plurality of capacitor structures comprising a support layer and a dielectric layer formed on the support layer, each of the support layers being formed on the corresponding second barrier layer, and a spacing between top surfaces of the support layers of adjacent capacitor structures being greater than a width of each of the plurality of contact structures along the first direction;
forming a plurality of bit lines, the substrate further comprising a second surface, the plurality of bit lines being formed on the second surface of the substrate, second end surfaces of the first active parts being exposed to the second surface, and the plurality of bit lines being electrically connected to the plurality of active structures through the second end surfaces of the first active parts; and
forming a bonding layer, the bonding layer being arranged on the second surface and connected to the plurality of word lines, the plurality of bit lines, and the plurality of capacitor structures through bonding structures.

14. The method for manufacturing a semiconductor structure according to claim 13, wherein the support layers have a different etching selectivity from the first barrier layers, or the support layers are made of the same material as the second barrier layers.

15. A memory device, formed by bonding the semiconductor structure according to claim 1 to a bonded wafer, wherein
the bonded wafer comprises a control circuit and a bonding interface, and the memory device is formed by bonding a bonding layer of the semiconductor structure to the bonding interface of the bonded wafer.
